(19) United States
(12) Patent Application Publication
(10) Pub. No.: US 2020/0174527 A1
(43) Pub. Date: Jun. 4, 2020

(54) Sliding Film Layer, Method for Preparing the same and Display Panel

(71) Applicant: Yungu (Gu'an) Technology Co., Ltd., Langfang (CN)

(72) Inventor: Dandan ZHOU, Langfang (CN)

(73) Assignee: Yungu (Gu'an) Technology Co., Ltd, Langfang (CN)

(21) Appl. No.: 16/779,760

(22) Filed: Feb. 3, 2020

Related U.S. Application Data
(63) Continuation of application No. PCT/CN2019/089028, filed on May 29, 2019.

(30) Foreign Application Priority Data
Aug. 10, 2018 (CN) 201810909602.7

(51) Int. Cl. G06F 1/16; G09F 9/30; G02B 1/10; H01L 51/00; F16C 33/20

(52) U.S. Cl. CPC G06F 1/1652; G06F 1/1609; G09F 9/301; F16C 33/201; H01L 51/0097; F16C 33/208; G02B 1/10

(57) ABSTRACT

By disposing the sliding film layer which is cut into a plurality of staggered segments in a screen, the sliding film layer slides when the screen is subjected to the impact force, so that the impact force is dispersed, and the anti-impact performance of the screen is effectively improved without affecting the bending performance of the screen. At least one first cutting surface is disposed on a top suffice of the sliding film layer, and extending at a preset angle with respect to the top surface, and the first cutting surface extends from the top surface into the sliding film layer, and at least one second cutting surface is disposed on a bottom surface of the sliding lam layer and staggered with the first cutting surface, and the second cutting surface extends from the bottom surface into the sliding film layer.

### CROSS-REFERENCE TO RELATED APPLICATIONS

This application is a continuation of International Application No. PCT/CN2019/089028 filed on May 29, 2019, which claims priority to Chinese patent application No. 201810909602.7 filed on Aug. 10, 2018. Both applications are incorporated herein by reference in their entireties.

### TECHNICAL FIELD

The present application relates to the field of fabrication of display panels, in particular to a sliding film layer, a method for preparing the same and a display panel.

### BACKGROUND

With the rapid development of display technologies, applications of a flexible screen have become more and more widespread. When the flexible screen is hit by a heavy object, the impact force in a hit portion cannot be dispersed, resulting in damage to a display device.

### SUMMARY

In view of this, the present application provides a sliding film layer, a method for preparing the same and a display panel, which may effectively improve the anti-impact performance of a screen without affecting the bending performance of the screen.

According to one embodiment of the present application, a sliding film layer is provided. At least one first cutting surface is disposed on a tap surface of the sliding film layer and extending at a preset angle with respect to the top surface, and the first cutting surface extends from the top surface into the sliding film layer, and at least one second cutting surface is disposed on a bottom surface of the sliding film layer and staggered with the first cutting surface, and the second cutting surface extends from the bottom surface into the sliding film layer. The first cutting surface and the second cutting surface are used to make the sliding film layer slide when the sliding film layer is subjected to the impact force so as to disperse the impact force.

According to another embodiment of the present application, a display panel is provided. The display panel includes a display layer and the sliding film layer described above. The sliding film layer is disposed below the display layer.

According to one embodiment of the present application, a method for preparing a sliding film layer is provided. The method includes: providing the sliding film layer; cutting from a top surface of the sliding film layer to a middle of the sliding film layer at a preset angle so as to form a first cutting surface; and cutting from a bottom surface of the sliding film layer to the middle of the sliding film layer so as to form a second cutting surface. The second cutting surface is staggered with the first cutting surface.

The sliding film layer, a method for preparing the same and the display panel are provided in the embodiments of the present application, by disposing the sliding film layer which is cut into a plurality of staggered segments in the screen, the sliding film layer slides when the screen is subjected to the impact force, so that the impact force is dispersed, and the anti-impact performance of the screen may be effectively improved without affecting the bending performance of the screen.

### BRIEF DESCRIPTION OF DRAWINGS

FIG. 1a is a top view schematic diagram of a sliding film layer according to an embodiment of the present application.

FIG. 1b is a schematic cross-sectional diagram of a sliding film layer according to an embodiment of the present application.

FIG. 1c is a schematic cross-sectional sliding diagram of a sliding film layer according to an embodiment of the present application.

FIG. 2 is a schematic structural diagram of a display panel according to an embodiment of the present application.

FIG. 3 is a schematic flowchart of a method for preparing a sliding film layer according to an embodiment of the present application.

FIG. 4 is a schematic structural diagram of a display panel according to an exemplary embodiment of the present application.

### DETAILED DESCRIPTION OF THE EMBODIMENTS

Technical solutions in embodiments of the present application are clearly and completely described in the following with reference to the accompanying drawings in the embodiments of the present application. It is obvious that the described embodiments are only a part of the embodiments of the present application, and not all of the embodiments. Based on the embodiments in the present application, all other embodiments obtained by those skilled in the art without creative efforts are within the scope of the present application.

Solutions are generally to increase the buffer material with better elasticity under the screen, but the total thickness of the screen is increased, and the beading performance of the flexible screen is affected.

Therefore, it is urgent to provide technologies for effectively improving the anti-impact performance of the screen without affecting the bending performance of the screen.

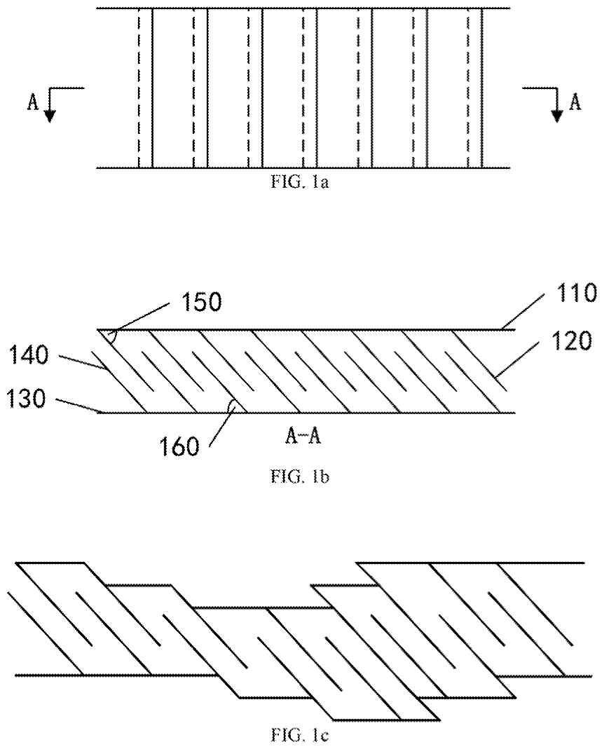

FIG. 1b is a schematic cross-sectional diagram of a sliding film layer according to an embodiment of the present application. A plurality of first cutting surfaces 120 are disposed on a top surface 110 of the sliding film layer, parallel to each other and extending at a preset angle 150 with respect to the top surface, and the plurality of first cutting surfaces 120 extend from the top surface 110 into the sliding film layer, and a plurality of second cutting surfaces 140 are disposed on a bottom surface 130 of the sliding film layer and staggered with the plurality of first cutting surfaces, and the plurality of second cutting surfaces 140 extend from the bottom surface 130 into the sliding film layer. The plurality of first cutting surfaces 120 and the plurality of second cutting surfaces 140 are used to make a cut portion of the sliding film layer misplace and slide when the sliding film layer is subjected to the impact force so as to disperse the impact force.

Specifically, the sliding film layer may be made of the material with certain stiffness, such as Polyethylene Terephthalate (PET), Polyethylene Naphthalate (PEN), Polyetheretherketone (PEEK) and the like. The material with certain stiffness may ensure that the sliding film layer quickly returns to its original state after sliding while certain support is provided for a structure above the sliding film layer. A structure of the sliding film layer is shown in FIG. 1a and FIG. 1b. After the sliding film layer is prepared, the sliding film layer may be cut by using a cutting process such as laser cutting or knife wheel cutting. Section A-A in FIG. 1b is a schematic structural diagram of the sliding film layer after cutting. It may be seen that cutting lines armed by all cutting surfaces in the section A-A may be parallel to each other or may have a certain angle. The plurality of first cutting surfaces 120 are cut from the top surface 110 of the sliding film layer to the middle of the sliding film layer at the preset angle 150. The preset angle may be 30 degrees, 45 degrees, 60 degrees or other angles, and the cutting depth may be from the top surface to a position of the sliding film layer which is ½, ⅔ away from the top surface or other positions of the sliding film layer. The plurality of second cutting surfaces 140 are cut from the bottom surface 130 of the sliding film layer to the middle of the sliding film layer. A preset angle 160 may be the same angle as the preset angle 150, the cutting depth may also be the same as the depth of the plurality of first cutting surfaces 120, and the preset angle and the cutting depth of the plurality of first cutting surfaces 120 and the plurality of second cutting surfaces 140 may be adjusted according to the needs of those skilled in the art, which is not specifically limited in the present application.

The sliding film layer designed above may be disposed below a display screen to play a certain supporting role, and when the display screen is subjected to the impact force, sliding of the sliding film layer may be shown in FIG. 1c, to disperse the impact force on the screen and improve the anti-impact performance of the screen. Due to certain stiffness of the sliding film layer, the sliding film layer may quickly return to its original state after sliding and provide sufficient support. At the same time, the thickness of the sliding film layer may be controlled within the range of 100 μm to 500 μm. Therefore, after the sliding film layer is added below the screen, the bending performance of the flexible screen is not affected. At the same time, due to the sliding characteristics and stiffness of the sliding film layer, the sliding film layer may disperse the impact force when subjected to the impact force, and the sliding film layer returns to its original state relying on the stiffness so as to provide support.

In an embodiment, the first cutting surface is parallel to the second cutting surface, and the preset angle is range from 30 degrees to 60 degrees. The first cutting surface extends from the top surface into the sliding film layer, for example, the first cutting surface extends from the top surface to a position of the sliding film layer which is ½ or ⅔ away from the top surface. The second cutting surface extends from the bottom surface into the sliding film layer, for example, the second cutting surface extends from the bottom surface to a position of the sliding film layer which is ½ or ⅔ away from the bottom surface.

Specifically, shown in FIG. 1b, the first cutting surface 120 and the second cutting surface 140 may be parallel to each other, and the preset angle 150 may be range from 30 degrees to 60 degrees, the preset angle within this range may ensure that the sliding film layer is smooth enough when sliding. If the angle is too large, the offset force in a horizontal direction is not enough to resist the impact force, which causes functions of the sliding film layer to be greatly reduced. If the angle is too small, the offset force in the horizontal direction is too large, which may reduce the flexibility of the sliding film layer and damage to the screen. Preferably, the preset angle 150 may be 45 degrees, and the preset angle of 45 degrees ensures that when the sliding film layer is subjected to the vertical impact force, the vertical impact force may be evenly dispersed in other directions, so that the sliding film layer may provide sufficient anti-impact performance fix the screen. The cutting depth may be from the top surface or bottom surface of the sliding film layer to the inside of the sliding film layer whose position is of ½ or ⅔ of the thickness of the entire sliding film layer. Specifically, the cutting depth should be at least ½ of the thickness of the entire sliding film layer. If the cutting depth is less than ½ of the thickness of the entire sliding film layer, the maximum sliding effect of the sliding film layer cannot be exerted; and the cutting depth should not be too deep, too deep may cause the strength of the entire sliding film layer to decrease, and the sliding film layer is easy to break when coping with the impact force. The preferred cutting depth may be ⅔ of the thickness of the entire sliding film layer, which may ensure that the first cutting surface 120 and the second cutting surface 140 have partially overlapping interval. When the sliding film layer slides for coping with the impact force, the maximum sliding effect of the sliding film layer may be exerted while the toughness and the strength of the sliding film layer are ensured.

Two cutting surfaces disposed in parallel may make the top surface and the bottom surface of the sliding film layer slide along a direction of the first cutting surface and the second cutting surface which are parallel to each other when the sliding film layer is subjected to the huge impact force. Therefore, the interaction force of connected parts in the sliding film layer are also canceled out, thereby ensuring that the flexibility of the sliding film layer is maximized and the sliding film layer is not easy to break when subjected to the excessive impact force.

In the embodiment, the first cutting surface and the second cutting surface are parallel to each other, the preset angle is range from 30 degrees to 60 degrees, and the cutting depth is disposed specifically, which may improve the anti-impact performance and the toughness of the sliding film layer, so that the anti-impact performance of the screen is improved.

In an embodiment, the sliding film layer includes a plurality of segments, and adjacent segments in the plurality of segments are connected by a micro spring.

Regardless of whether the structure of the entire screen includes or does not include a support layer, the sliding film layer may include the plurality of segments, and then the adjacent segments in the plurality of segments are connected by the micro spring. For example, if the screen includes a display layer, a segmented sliding film layer and the support layer from top to bottom, an optically clear adhesive may be coated on an uncut portion of the segmented sliding film layer to adhere the display layer, the segmented sliding film layer and the support layer together. The micro spring is disposed between the adjacent segments in the sliding film layer, which may make the sliding film layer not only have the sliding effect of the film layer itself but also provide the additional buffer performance through the elastic force of the micro spring, so that the effect of dispersing the impact force of the sliding film layer is enhanced, better anti-impact performance may be provided for the screen, and the addition of the micro spring still does not affect the bending performance of the flexible screen.

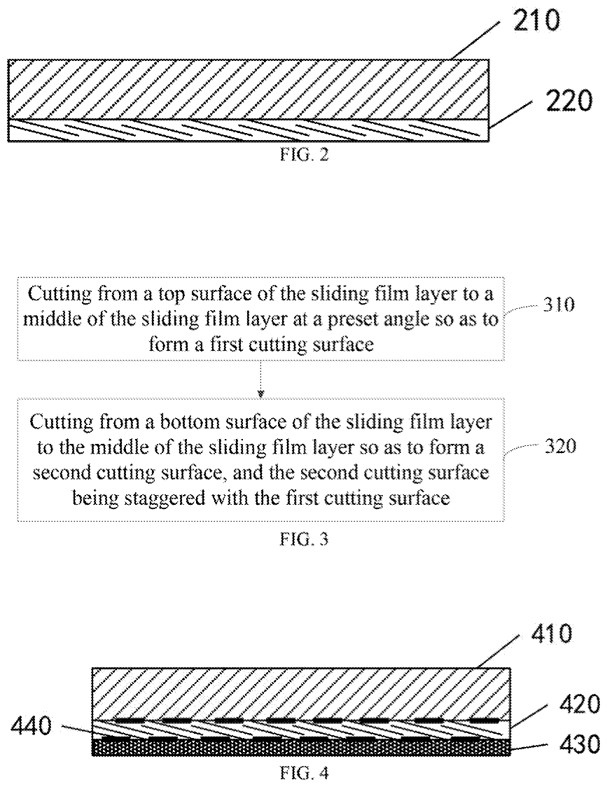

FIG. 2 is a schematic structural diagram of a display panel according to an embodiment of the present application. The display panel includes a display layer 210 and a sliding film layer 220. The sliding film layer 220 is disposed below the display layer 210.

The display layer 210 may be a general term in the embodiment. The display layer 210 may include, for example, an external protective layer, an internal protective layer, a touch layer, a flexible Active-Matrix Organic Light. Emitting Diode (AMOLED) display panel and the like. It should be understood that the thickness of the sliding film layer 220 and the display layer 210 in FIG. 2 is merely examples, and the actual thickness ratio is not limited thereto.

The sliding film layer 220 which has been cut is disposed below the display layer 210. The sliding film layer 220 has certain stiffness and sliding characteristics, which may effectively improve the anti-impact performance of the screen; meanwhile, the thickness of the sliding film layer 220 is thinner than the conventional buffer layer, so that the bending performance of the screen may not be affected after adding the sliding film layer 220.

In an embodiment, a first adhesive layer is also included between the sliding film layer and the display layer, and the first adhesive layer includes a plurality of units which are distributed laterally at a preset distance to adhere the sliding film layer and the display layer together.

The first adhesive layer may also be disposed between the sliding film layer and the display layer. The first adhesive layer may be formed by coating with an optically clear adhesive. The sliding film layer and the display layer may be adhered together by using, for example, the OCA (Optically Clear Adhesive). The sliding film layer and the display layer are adhered together mainly by the OCA having characteristics of colorless and transparency, more than 90% light transmittance and good bending strength. At the same time, in order to ensure that the maximum performance of the sliding film layer may be exerted, the OCA may not be coated on all surfaces of the sliding film layer, but only a part of the sliding film layer, so that the first adhesive layer includes the plurality of units which are distributed laterally at the preset distance and between the sliding film layer and the display layer. Therefore, the sliding film layer that is not coated with the OCA may still slide to disperse the impact force subjected. Preferably, the OCA is coated on the top surface of the sliding film layer and only coated on a place where the sliding film layer is not cut, and the OCA is not coated on a place where the top surface of the sliding film layer is cut. In this way, the sliding effect of the sliding film layer may be maximized, and the maximum anti-impact performance is provided for the screen.

In the embodiment, the optically transparent adhesive is coated dispersedly between the sliding film layer and the display layer at the preset distance, the purpose of which is to better exert the sliding effect of the sliding film layer so as to better disperse the impact force subjected, so that better anti-impact performance may be provided for the screen.

In an embodiment, the display plane further includes a support layer, and the support layer is disposed below the sliding film layer to support the sliding film layer and the display layer.

After the sliding film layer is disposed below the display layer, the support layer may be further disposed below the sliding film layer. The role of the support layer is to provide more support force for the sliding film layer and the display layer on the basis of the sliding film layer so as to ensure the solidity of the entire display panel. The support layer may be made of the heat-deformable material, or the soft material with certain elastic recovery performance, or the same material as the sliding film layer, and the material of the support layer may be chose by those skilled in the art according to the needs, which is not limited in the present application.

The support layer in the embodiment is disposed at the lowermost layer, i.e., the support layer is disposed below the display layer and the sliding film layer, which may provide sufficient support force for the screen to make the structure of the entire screen more sturdy and durable.

In an embodiment, a second adhesive layer is also included between the sliding film layer and the support layer, and the second adhesive layer includes a plurality of units which are distributed laterally at a preset distance to adhere the sliding film layer and the support layer together.

Specifically, as described in the above embodiments, the first adhesive layer may include the plurality of units which are distributed laterally at the preset distance and between the sliding film layer and the display layer to adhere the sliding film layer and the display layer together, so the display layer is adhered to the top surface of the sliding film layer. In the embodiment, since the support layer is also disposed below the sliding film layer, the second adhesive layer may include the plurality of units which are distributed laterally at the preset distance and between the bottom surface of the sliding film layer and the support layer, and the second adhesive layer may be formed by coating with the optically clear adhesive to adhere the sliding film layer and the, support layer together, and the sliding film layer and the support layer may be adhered by, for example, the OCA. Preferably, the optically clear adhesive is coated on the bottom surface of the sliding film layer and only coated on a place where the sliding film layer is not cut, and the optically clear adhesive is not coated on a place where the bottom surface of the sliding film layer is cut. In this way, the maximum sliding effect of the sliding film layer may be exerted, and the maximum anti-impact performance is provided for the screen.

The sliding film layer in the embodiment is located between the display layer and the support layer, the top surface of the sliding film layer is adhered to the display layer, and the bottom surface of the sliding film layer is adhered to the support layer. Both of them are adhered together by coating dispersedly the optically clear adhesive at the preset distance, so that the sliding effect of the sliding film layer may be effectively exerted on the basis of the entire screen having enough support force, so as to provide the screen with the effective anti-impact performance.

In an embodiment, the first adhesive layer and the second adhesive layer are disposed on an uncut portion of the sliding film layer.

For example, if the screen includes the display layer, the segmented sliding film layer, and the support layer from top to bottom, the optically clear adhesive may be coated on the uncut portion of the segmented sliding film layer to adhere the display layer, the segmented sliding film layer and the support layer together. It can be known that the optically clear adhesive is coated dispersedly between the sliding film layer and the display layer at the preset distance, the purpose of which is to better exert the sliding effect of the sliding film layer so as to better disperse the impact force subjected, so that better anti-impact performance may be provided for the screen.

FIG. 3 is a schematic flowchart of a method for preparing a sliding film layer according to an embodiment of the present application. The method includes:

310: cutting from a top surface of the sliding film layer to a middle of the sliding film layer at a preset angle so as to form a first cutting surface.

The sliding film layer is cut from the top surface to the middle at the preset angle by using the cutting process such as laser cutting or knife wheel cutting. The cutting preset angle may be 30 degrees, 45 degrees, 60 degrees or other angles, and the cutting depth may be from the top surface to a position of the sliding film layer which is ½, ⅔ away from the top surface or other positions of the sliding film layer, which may be adjusted by those skilled in the art according to the needs and are not specifically in the present application. The plurality of first cutting surfaces may be parallel to each other to ensure that the interaction force of connected parts in the sliding film layer may be canceled out when the sliding film layer is subjected to the huge impact force, thereby ensuring that the flexibility of the sliding film layer is maximized, and the sliding film layer is not easy to break when subjected to the excessive impact force.

320: cutting from a bottom surface of the sliding film layer to the middle of the sliding film layer so as to form a second cutting surface, and the second cutting surface being staggered with the first cutting surface.

The sliding film layer is cut from the bottom surface by using the cutting process similar to step 310 to form the second cutting surface. The second cutting surface may be staggered with the first cutting surface. Advantages of staggered setting are that the sliding film layer may be evenly stressed and will not break due to the excessive force at one place when subjected to the impact force.

Preferably, the preset angle may be 45 degrees, and the preset angle of 45 degrees ensures that when the sliding film layer is subjected to the vertical impact force, the vertical impact force may be evenly distributed in other directions, so that the sliding film layer may provide sufficient anti-impact performance for the screen. The first cutting surface and the second cutting surface may also be parallel to each other, which may ensure that the top surface and the bottom surface only slide along the direction of the first cutting surface and the second cutting surface parallel to each other when the sliding film layer is subjected to the impact force. Therefore, the interaction force of the connected parts in the sliding film layer are also canceled out, thereby ensuring that the flexibility of the sliding film layer is maximized, and the sliding film layer is not easy to break when subjected to the excessive impact force.

In this embodiment, by cutting the top surface and the bottom surface of the sliding film layer, the sliding film layer has the sliding effect, which may effectively disperse the impact force and ensure that the anti-impact performance of the screen is improved after adding the sliding film layer. The thickness, of the sliding film layer is thinner than the conventional buffer layer, which may ensure that the bending performance of the screen is not affected after adding they sliding film layer.

In an embodiment, the method further includes: coating dispersedly an optically clear adhesive on the top surface of the sliding film layer at a preset distance; and adhering the sliding film layer and the display layer together by the optically clear adhesive.

The optically clear adhesive may be dispersedly coated on the top surface of the sliding film layer at the preset distance. The optically clear adhesive may be, for example, an OCA. Advantages of coating dispersedly are that the maximum sliding effect of the sliding film layer may be exerted and the maximum anti-impact performance is provided for the screen. Then the sliding film layer and the display layer are adhered together by the optically clear adhesive having the viscosity.

It needs to be understood that the sliding film layer may be cut first, and then the optically clear adhesive is coated on the cut sliding film layer for adhesion. Or the optically clear adhesive which is required is coated on the uncut sliding film layer first, and then the cutting operation is performed on the entire sliding film layer coated with the optically clear adhesive by using the cutting process such as laser cutting or knife wheel cutting. Those skilled in the art may choose whether to coat the optical clear adhesive first or to cut the sliding film layer first according the needs, which is not specifically limited in the present application.

It should be known that the optically clear adhesive is coated dispersedly between the sliding film layer and the display layer at the preset distance, the purpose of which is, to better exert the sliding effect of the sliding film layer so as to better disperse the impact force subjected, so that better anti-impact performance may be provided for to the screen.

In an embodiment, the method further includes: coating an optically clear adhesive on an uncut portion of the top surface of the sliding film layer; and adhering the sliding film layer and the support layer together by the optically clear adhesive. In other words, the sliding film layer may be cut first, and then the optically clear adhesive may be coated on the top surface of the cut sliding film layer for the adhesion, which may better exert the sliding effect of the sliding film layer so as to better disperse the impact force subjected, so that better anti-impact performance may be provided for the screen.

In an embodiment, the method further includes: coating dispersedly an optically clear adhesive on the bottom surface of the sliding film layer at a preset distance; and adhering the sliding film layer and the support layer together by the optically clear adhesive.

Similar to the above embodiments, a support layer is also disposed below the sliding film layer. The process and the material used for the adhesion method of the sliding film layer and the support layer are similar as that of the sliding film layer and the display layer, which are not repeated herein.

The support layer is adhered below the sliding film layer, which may provide sufficient support for the screen, so that the structure of the entire screen is more sturdy and durable.

In an embodiment, the method further includes: coating an optically clear adhesive on an uncut portion of the bottom surface of the sliding film layer; and adhering the sliding film layer and a support layer together by the optically clear adhesive. In other words, the sliding film layer may be cut first, and then the optically clear adhesive may be coated on the bottom surface of the cut sliding film layer for the adhesion, which may better exert the sliding effect of the sliding film layer.

In an embodiment, the cutting from a top surface of the sliding film layer to a middle of the sliding film layer at a preset angle so as to form a first cutting surface includes: cutting from the top surface of the sliding film layer to a position of the sliding film layer which is ½ or ⅔ away from the top surface at the angle between 30 degrees to 60 degrees so as to form the first cutting surface; and the cutting from a bottom surface of the sliding film layer to the middle of the sliding film layer so as to form a second cutting surface includes: cutting from the bottom surface of the sliding film layer to a position of the sliding film layer which is ½ or ⅔ away from the bottom surface at the angle between 30 degrees to 60 degrees so as to form the second cutting surface. When the sliding film layer slides for coping with the impact force, not only the maximum sliding effect of the sliding film layer in the embodiment may be exerted, but also the toughness and the strength of the sliding film layer may be ensured.

FIG. 4 is a schematic structural diagram of a display panel according to an exemplary embodiment of the present application. The display panel includes a display layer 410, a sliding film layer 420 and a support layer 430. The sliding film layer 420 is adhered between the display layer 410 and the support layer 430 by dispersedly coating an Optical Coating Adhesive (OCA) 440 at a preset distance.

The display layer 410 may include, for example, an external protective layer and an internal protective layer, a touch layer, a flexible active-matrix organic, light emitting diode display panel and the like.

The sliding film layer 420 is preferably made of the material with certain stiffness, and the thickness of the sliding film layer 420 is controlled within the range of 100 μm to 500 μm, which ensures that the sliding film layer 420 may quickly return to its original state after sliding. The thickness is controlled so as not to affect the bending performance of the entire screen. The first cutting surface and the second cutting surface of the sliding film layer 420 are formed by using laser cutting. The first cutting surface is extending at a preset angle with respect to a top surface of the sliding film layer 420, the preset angle is 45 degrees, and the second cutting surface and the first cutting surface are parallel to each other and are staggered. The sliding film layer is coated with the OCA 440 for adhesion with the display layer 410 and the support layer 430. As shown in FIG. 4, the OCA 440 is only coated on an uncut portion of the sliding film layer 420 to ensure that the sliding film layer 420 may still slide to a certain degree after adhering. Another implementing method is that the OCA may be dispersedly coated on the uncut sliding film layer at a preset distance first, and then the entire sliding film layer with the OCA is cut.

The support layer 430 is mainly used to support the display layer 410 and the film layer 420.

In the display panel provided in the above methods, the sliding film layer 420 is adhered to the display layer 410 and the support layer 430 by the OCA 440 dispersedly coated, which provides the effective sliding effect and may effectively disperse the impact force that the display panel is subjected. The control of the thickness makes the display panel have the anti-impact performance and the bending performance; at the same time, the support layer 430 may help the sliding film layer 420 which has the certain stiffness to return to its original state quickly after sliding, and provide certain sturdiness and durability for the display panel, so that the display panel has reliable performance.

The above are only specifically implementing methods of the present application, and are not intended to limit the protective scope of the present application. Any person skilled in the art may easily think of modifications or replacements within the technical scope disclosed in the present application, which should be included within the protective scope of the present application. Therefore, the protection scope of the present application shall be subject to the protection scope of the claims.

What is claimed is:

1. A sliding film layer, comprising:
at least one first cutting surface disposed on a top surface of the sliding film layer, extending at a preset angle with respect to the top surface and extending from the top surface into the sliding film layer; and
at least one second cutting surface disposed on a bottom surface of the sliding film layer, staggered with the first cutting surface and extending from the bottom surface into the sliding film layer,
wherein the sliding film layer slides under an impact force to disperse the impact force, due to the first cutting surface and the second cutting surface.

2. The sliding film layer according to claim 1, wherein the first cutting surface is parallel to the second cutting surface, the preset angle ranges from 30 degrees to 60 degrees, the first cutting surface extends from the top surface to a position of the sliding film layer which is ½ or ⅔ away from the top surface, and the second cutting surface is extends from the bottom surface to a position of the sliding film layer which is ½ or ⅔ away from the bottom surface.

3. The sliding film layer according to claim 2, wherein the first cutting surface is parallel to the second cutting surface, and the preset angle is 45 degrees.

4. The sliding film layer according to claim 1, wherein the sliding film layer comprises a plurality of segments, and adjacent segments in the plurality of segments are connected by a micro spring.

5. The sliding film layer according to claim 1, wherein the material of the sliding film layer comprises at least one of polyethylene glycol terephthalate, polynaphthalene glycol phthalate and polyether-ether-ketone.

6. The sliding film layer according to claim 1, further comprising a plurality of first cutting surfaces parallel to each other, and a plurality of second cutting surfaces parallel to each other.

7. A display panel, comprising:
a display layer; and
a sliding film layer, comprising at least one first cutting surface disposed on a top surface of the sliding film layer, extending at a preset angle with respect to the top surface and extending from the top surface into the sliding film layer; and at least one second cutting surface disposed on a bottom surface of the sliding film layer, staggered with the first cutting surface and extending from the bottom surface into the sliding film layer,
wherein the sliding film layer is disposed below the display layer, and the sliding film layer slides under an impact force to disperse the impact force, due to the first cutting surface and the second cutting surface.

8. The display panel according to claim 7, further comprising:
a first adhesive layer disposed between the sliding film layer and the display layer,
wherein the first adhesive layer comprises a plurality of units which are distributed laterally at a preset distance to adhere the sliding film layer and the display layer together.

9. The display panel according to claim 8, wherein the material of the first adhesive in layer is an optically clear adhesive.

10. The display panel according to claim 7, further comprising:
a support layer disposed below the sliding film layer to support the sliding film layer and the display layer.

11. The display panel according to claim 10, further comprising:
a second adhesive layer disposed between the sliding film layer and the support layer,
wherein the second adhesive layer comprises a plurality of units which are distributed at a preset distance to adhere the sliding film layer and the support layer together.

12. The display panel according to claim 8, wherein the first adhesive layer is disposed on an uncut portion of the sliding film layer.

13. The display panel according to claim 11, wherein the second adhesive layer is disposed on an uncut portion of the sliding film layer.

14. The display panel according to claim 11, wherein the material of the second adhesive layer is an optically clear adhesive.

15. A method for preparing a sliding film layer, comprising:
providing the sliding film layer;
cutting from a top surface of the sliding film layer to a middle of the sliding film layer at a preset angle so as to form a first cutting surface; and
cutting from a bottom surface of the sliding film layer to the middle of the sliding film layer so as to form a second cutting surface.
wherein the second cutting surface is staggered with the first cutting surface.

16. The method according to claim 15, further comprising:
coating dispersedly an optically clear adhesive on the top surface of the sliding film layer at a preset distance; and
adhering the sliding film layer and a display layer together by the optically dear adhesive.

17. The method according to claim 15, further comprising:
coating an optically clear adhesive on an uncut portion of the top surface of the sliding film layer; and
adhering the sliding film layer and a display layer together by the optically clear adhesive.

18. The method according to claim 15, further comprising:
coating dispersedly an optically clear adhesive on the bottom surface of the sliding film layer at a preset distance; and
adhering the sliding film layer and a support layer together by the optically clear adhesive.

19. The method according to claim 15, further comprising:
coating an optically clear adhesive on an uncut portion of the bottom surface of the sliding film layer; and
adhering the sliding film layer and a support layer together by the optically clear adhesive.

20. The method according to claim 15, wherein the cutting from a top surface of the sliding film layer to a middle of the sliding film layer at a preset angle so as to form a first cutting surface comprises:
cutting from the top surface of the sliding film layer to a position of the sliding film layer which is ½ or ⅔ away from the top surface at the angle between 30 degrees to 60 degrees so as to form the first cutting surface, and
the cutting from a bottom surface of the sliding film layer to the middle of the sliding film layer so as to form a second cutting surface comprises:
cutting from the bottom surface of the sliding film layer to a position of the sliding film layer which is ½ or ⅔ away from the bottom surface at the angle between 30 degrees to 60 degrees so as to form the second cutting surface.
